(19) United States
(12) Patent Application Publication
(10) Pub. No.: US 2014/0151865 A1
(43) Pub. Date: Jun. 5, 2014

(54) SEMICONDUCTOR DEVICE PACKAGES PROVIDING ENHANCED EXPOSED TOE FILLETS

(71) Applicant: Thomas H. Koschmieder, Austin, TX (US)

(72) Inventor: Thomas H. Koschmieder, Austin, TX (US)

(21) Appl. No.: 13/689,845

(22) Filed: Nov. 30, 2012

(51) Int. Cl. H01L 23/495; H01L 21/56

(52) U.S. Cl. CPC H01L 23/495; H01L 21/56
USPC 257/676; 438/113

(57) ABSTRACT

A mechanism is provided by optically inspectable surface mount bonding of no-leads packages is enhanced. Embodiments of the present invention use a lead frame within the no-leads package that provides a plated surface not only along the bottom of the package but also in a direction substantially parallel to the sides of the package. Since the plated surface has a greater affinity for solder during a reflow process than does the bare metal of the lead frame, toe fillets have a greater chance of forming in a manner that can be optically inspected during a test for quality of the bonding of the package to a printed circuit board. In addition, a mold chase that conforms to the shape of the lead frame is used to prevent mold compound from adhering to the portions of the lead frame external to the package that are used as electrical contacts.

### BACKGROUND

1. Field

This disclosure relates generally to semiconductor device packaging, and more specifically, to flat no-leads packages that provide enhanced exposed toe fillets for optical inspection after coupling a semiconductor device package to a printed circuit board.

2. Related Art

Space concerns in assembling semiconductor devices has led to development of semiconductor device packages that have no leads extending from beyond the perimeter of the package. These packages, such as quad-flat no-leads and power quad-flat no-leads (QFN/PQFN) packages and dual-flat no-leads (DFN) packages, are surface mounted to printed circuit boards (PCBs). The lack of leads extending from the package results in a mounted package consuming less space on the PCB and therefore permitting higher density mounting of packages on the PCB.

The surface mount process used for mounting no-leads packages on a PCB typically uses a solder reflow process that electrically and mechanically bonds the contacts on a no-leads package to contacts on the PCB. Surface tension of the solder to portions of the contacts that have an affinity for solder results in some of the solder extending beyond the edge of the mounted component along the PCB contact, and rising along the edge of the contact of the mounted component away from the PCB. This forms a “toe fillet” that can be automatically optically inspected as an aid in determining whether the contacts of the package and the PCB are bonded.

In a typical no-leads package, the electrical contacts are present on the bottom (or active) surface of the package. To enhance the contacts' affinity for solder, the contacts are often plated with a solderable metal such as tin. During singulation, a portion of an electrical contact is exposed along the side of the package, but not all of the exposed portion of the electrical contact is plated. Further, the side of the contact may be roughened up due to the singulation processes and also is subject to oxidization, both of which can affect solder affinity.

Thus, there may be a lesser affinity for solder on the portion of the contact along the side of the package. This lesser affinity can affect the formation of a toe fillet, and thereby cause the bonded package to fail automatic optical inspection even though the bond of the package to the PCB is adequate along the active surface of the package. It is therefore desirable to provide a no-leads package that consistently provides for well-formed toe fillets so that bonded parts do not wrongly fail an optical inspection process.

### BRIEF DESCRIPTION OF THE DRAWINGS

The present invention may be better understood, and its numerous objects, features, and advantages made apparent to those skilled in the art by referencing the accompanying drawings.

FIG. 1 is a simplified block diagram illustrating an assembly in which a semiconductor device package is mounted on a printed circuit board.

FIG. 2 is a simplified block diagram illustrating an assembly in which a semiconductor device package providing embodiments of the present invention is mounted to a printed circuit board.

FIG. 3 is a simplified block diagram illustrating a cross-section of a lead frame usable to provide embodiments of the present invention.

FIG. 4 is a simplified block diagram illustrating a plan view of a portion of the lead frame, according to an embodiment of the present invention.

FIG. 5 is a simplified block diagram illustrating a cross-section of a mold chase configured to implement embodiments of the present invention.

FIG. 6 is a simplified block diagram illustrating a plan view of features on mold chase.

FIG. 7 is a simplified block diagram illustrating a cross-sectional view of a lead frame at a first stage of processing a semiconductor device package, incorporating embodiments of the present invention.

FIG. 8 is a simplified block diagram illustrating a cross-sectional view of a next stage of processing a semiconductor device package, incorporating embodiments of the present invention.

FIG. 9 is a simplified block diagram illustrating a cross-sectional view of a further stage of processing the semiconductor device package, incorporating embodiments of the present invention.

FIG. 10 is a simplified block diagram illustrating a cross-sectional view of a further stage of processing the semiconductor device package, incorporating embodiments of the present invention.

FIG. 11 is a simplified block diagram illustrating a cross-sectional view of the semiconductor device package incorporating embodiments of the present invention subsequent to singulation.

FIG. 12 is a perspective view of a portion of a bottom edge of a semiconductor device package incorporating embodiments of the present invention.

The use of the same reference symbols in different drawings indicates identical items unless otherwise noted. The figures are not necessarily drawn to scale.

### DETAILED DESCRIPTION

A mechanism is provided by which formation of toe fillets during surface mount bonding of no-leads packages is enhanced for optical inspection. Embodiments of the present invention use a lead frame within the no-leads package that provides a plated surface not only along the bottom of the package but also in a direction substantially parallel to the sides of the package. Since the plated surface has a greater affinity for solder during a reflow process than does the bare metal of the lead frame, toe fillets have a greater chance of forming in a manner that can be optically inspected during a test for quality of the bonding of the package to a printed circuit board. In addition, a mold chase that conforms to the shape of the lead frame is used to prevent mold compound from adhering to the portions of the lead frame external to the package that are used as electrical contacts.

Flat no-leads packages, such as quad-flat no-leads (QFN) and dual-flat no-leads (DFN) packages are used to physically and electrically connect integrated circuit die to printed circuit boards. QFN packages can be near chip scale encapsulated packages having a lead frame substrate. The package uses perimeter lands on the bottom of the package to provide electrical contact to the printed circuit board (PCB). A die attach paddle can be exposed on the bottom surface of the package to provide a thermal path or electrical path when soldered to the PCB. Flat no-leads packages are bonded to a PCB using surface mounting techniques.

Surface mount technology is used with a PCB that has flat, tin, silver, nickel palladium, or gold-plated copper pads, also called solder pads. A solder paste (e.g., a mixture of flux and solder particles) is applied to all the solder pads using a screen printing process or a jet-printing process. After pasting, the PCB is made available to a pick-and-place machine that places components (e.g., a QFN package) onto the appropriate locations of the PCB. The PCB along with the placed components is then subjected to a solder reflow process, in which the board is exposed to a sufficient temperature to melt the solder particles in the solder paste, thereby bonding the component leads to the pads on the circuit board. Surface tension of the molten solder keeps the components in place and aligns the components on the pads.

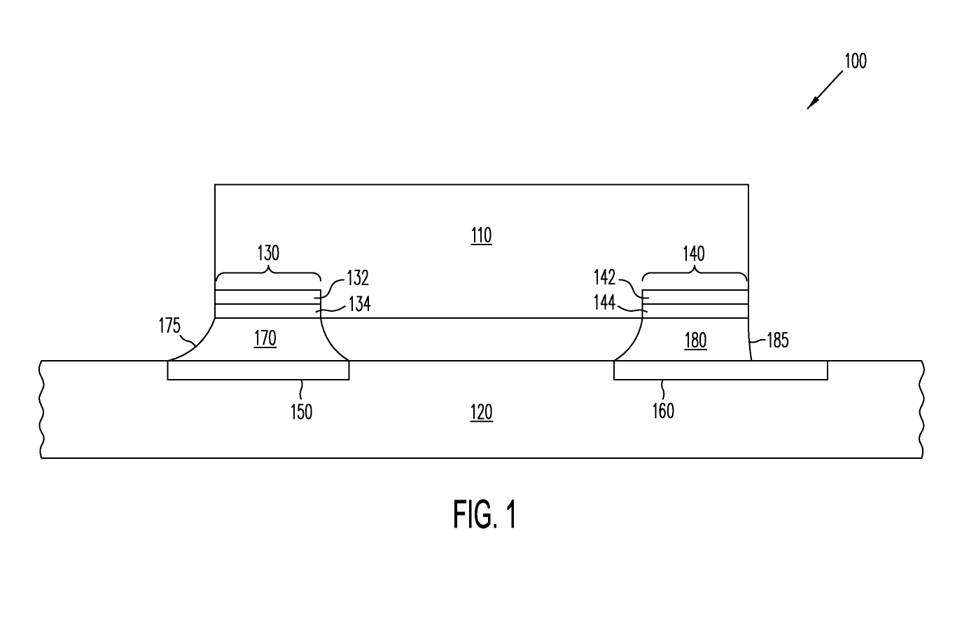

FIG. 1 is a simplified block diagram illustrating an assembly in which a semiconductor device package is mounted on a printed circuit board. In assembly 100, semiconductor device package 110 is mounted on PCB 120 using a solder reflow process, as described above. Semiconductor device package 110 can be a QFN package having electrical contacts 130 and 140. Electrical contact 130 includes a base metal 132 that is part of a lead frame used during manufacture of semiconductor device package 110. Base metal 132 can be a variety of electrically conductive metals, and is most commonly copper. Electrical contact 130 further includes a plated metal 134 that is provided to enhance adhesion of reflowed solder to electrical contact 130. Examples of such plating metals include, for example, tin, gold, and silver, and alloys thereof. Similarly, electrical contact 140 includes a base metal layer 142 and a plated metal layer 144.

Electrical contacts 130 and 140 of the semiconductor device package are electrically coupled to PCB contacts 150 and 160 through solder connections 170 and 180. As discussed above, solder connections 170 and 180 are formed using a solder reflow process known in the art. During the solder reflow process, due to surface tension between the solder and the contact metals having an affinity for the solder, solder features 175 and 185 are formed. Due to the singulation process by which the QFN package is manufactured, the contact metals along the sides of semiconductor device package 110 can be of irregular smoothness and can also have an indeterminate amount of plating metal exposed. In the case of electrical contact 130, a sufficient amount of plating metal 134 is exposed along the side surface of the contact and the surface is of a sufficient smoothness to provide a well formed toe fillet in solder feature 175. On the other hand, the manufacturing process causes either an insufficient amount of plating metal, oxidation, or an irregular surface on the side of electrical contact 140, thereby preventing a well formed toe fillet from forming in solder feature 185.

A typical testing procedure to determine whether a PCB and its components have been assembled correctly is to optically inspect the PCB assembly. Optical inspection involves checking for missing or misaligned components and solder bridging. With regard to no-leads package mounting, optical inspection often looks for a well-formed toe fillet as an indication of a good solder bond, since the underside of the components cannot be directly inspected. If the toe fillet is missing or is ill-formed, as with solder feature 185, then the component will not pass visual inspection, even though there may be a good electrical coupling along the underside of the component.

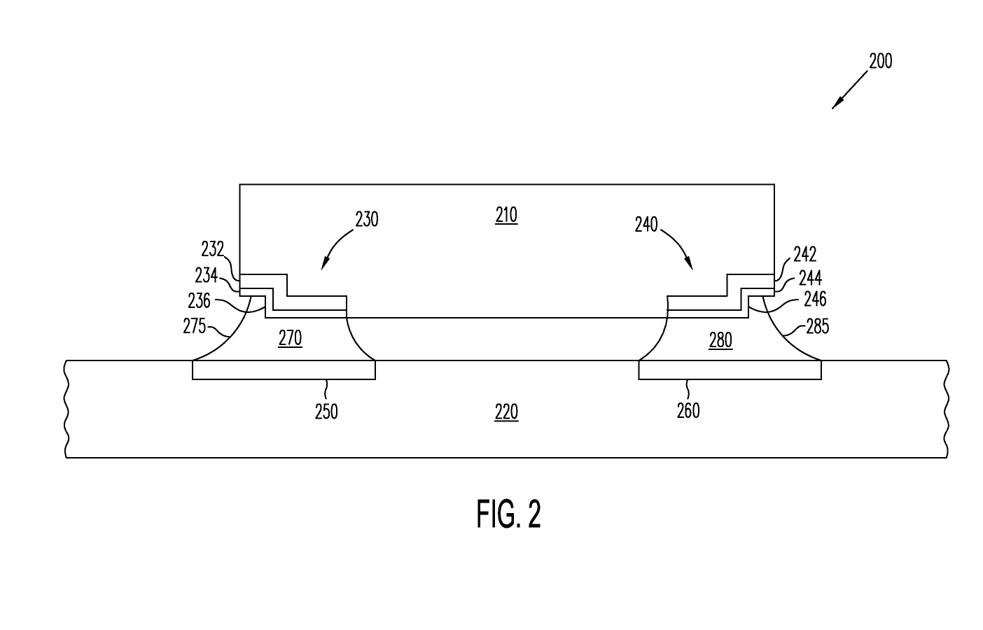

FIG. 2 is a simplified block diagram illustrating an assembly in which a semiconductor device package providing embodiments of the present invention is mounted to a printed circuit board. In assembly 200, semiconductor device package 210 is mounted on PCB 220 using a solder reflow process similar to that discussed above. As with FIG. 1, semiconductor device package 210 can be a QFN package having electrical contacts 230 and 240. Similarly, as with FIG. 1, electrical contact 230 includes a base metal 232 that is part of a lead frame used during manufacture of semiconductor device package 210. Base metal 232 can be a variety of electrically conductive metals (e.g., copper). Electrical contact 230 further includes a plated metal 234 that is provided to enhance adhesion of reflowed solder to electrical contact 230. Examples of such plating metals include tin, gold, silver, nickel, palladium, and alloys thereof. Electrical contact 240 also includes a base metal layer 242 and a plated metal layer 244.

Each electrical contact 230 and 240 includes a bend or a step that results in a surface of the electrical contact (e.g., surfaces 236 and 246, respectively) that is substantially aligned with the sides of the package or at least has a directional component aligned with the sides of the package. As will be discussed more fully below, these bends are created during fabrication of a lead frame that forms the electrical contacts. As illustrated, an advantage of the bends in the electrical contacts is an increased plated area in a direction aligned with the sides of the package, which can substantially improve adhesion of reflowed solder to the contacts along that direction.

Electrical contacts 230 and 240 of the semiconductor device package are electrically coupled to PCB contacts 250 and 260 through solder connections 270 and 280. During the solder reflow process, as discussed above, surface tension between the solder and the electrical contact metals having affinity for the solder causes solder features 275 and 285 to be formed at solder connections 270 and 280, respectively. Due to the presence of a plated, non-sawn surface in a direction aligned with the sides of the semiconductor device package (e.g., surfaces 236 and 246), solder features 275 and 285 provide more reliably formed toe fillets as compared with solder features 175 and 185 discussed above. Thus, package assemblies incorporating embodiments of the present invention can be expected to more consistently pass an optical inspection that uses the presence of well-formed toe fillets as an indicator of a good solder bond.

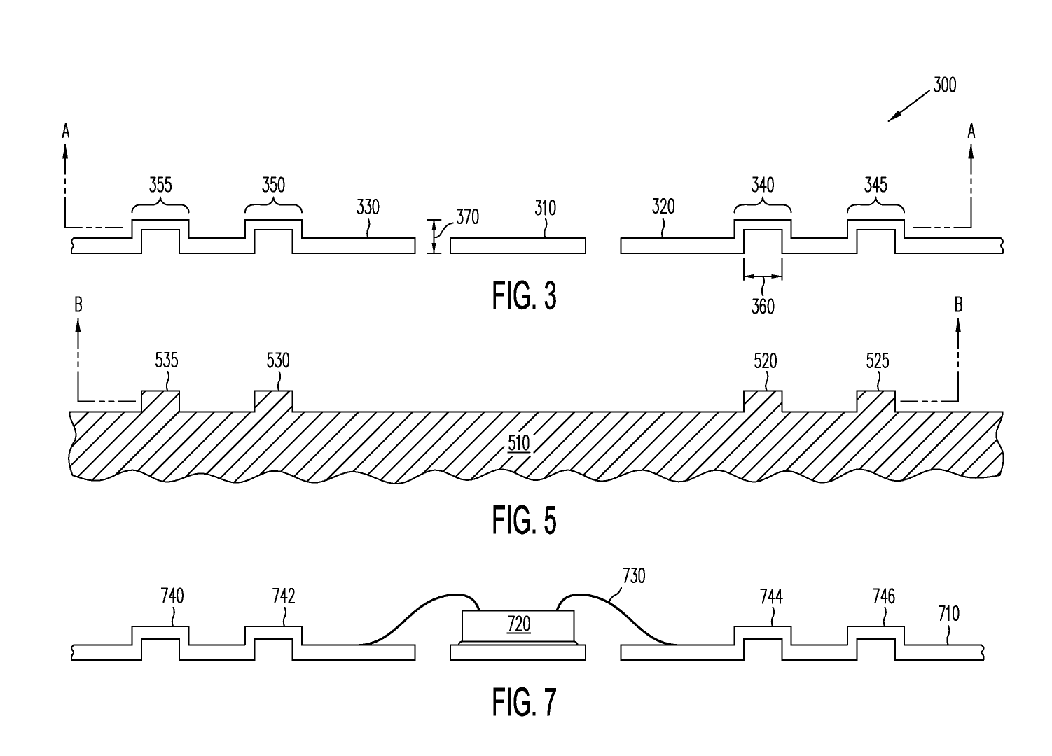

FIG. 3 is a simplified block diagram illustrating a cross-section of a lead frame usable to provide embodiments of the present invention. Lead frame 300 includes a die pad 310 and leads 320 and 330. Typically, lead frame 300 is made of copper or a copper alloy. In order to enhance adhesion of solder to the lead frame, one or both surfaces of the lead frame can be plated with, for example, tin, silver, or gold, or an alloy thereof. Plating of the lead frame surfaces can be performed by the lead frame vendor during fabrication of the lead frame itself, or can be performed subsequent to an encapsulation process forming the semiconductor device package.

Lead 320 includes a bend 340 and a bend 345. Similarly, lead 330 includes a bend 350 and a bend 355. The bent regions of the leads form portions of the semiconductor device package contacts that are substantially aligned with the sides of the semiconductor device package (e.g., surfaces 236 and 246 of contacts 230 and 240). As will be discussed more fully below, these contacts can be formed by singulating through the bent regions of the leads. In order to provide sufficient room in a lead bend to allow for singulation (e.g., sawing), a width 360 of bend 240 should be sufficient to allow for a width of a slot formed by the saw blade as well as any wobble in the saw blade or alignment errors in the sawing process. Further, it is desirable in some embodiments to provide approximately 0.1 mm depth of the step contact on the finished semiconductor device package. Thus, in this example, 0.1 mm on the side of the bend toward die pad 310 beyond the width of the saw slot plus wobble/alignment region should be provided in the embodiment illustrated.

The illustrated embodiment provides two bends on each lead. For example, bend 340 provides a contact for a semiconductor device package that includes die pad 310. Bend 345 provides a contact for a semiconductor device package that includes a die pad to the right of the illustrated section. In this case, two singulation processes will be performed to separate the packages upon encapsulation. In another embodiment, a single singulation process can be used, if only one bend is provided in the region that separates neighboring packages.

Alternative shapes for the bend region described above are also usable by embodiments of the present invention (e.g., curved shapes and the like). In an alternate embodiment, a single bend can be used to provide side contacts for neighboring parts. Upon singulation through the single bend, the remains on each part are the side contacts used for toe fillet formation. Though industry practice is to have a saw singulation to lead direction be perpendicular, there is no requirement for a perpendicular relationship.

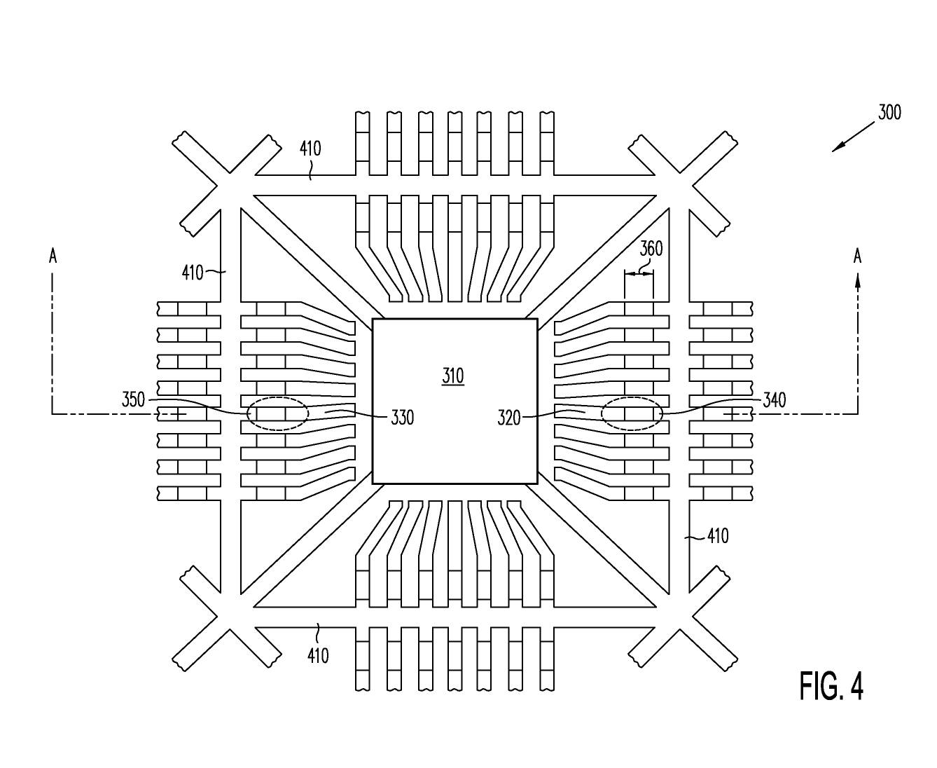

FIG. 4 is a simplified block diagram illustrating a plan view of a portion of the lead frame illustrated in FIG. 3, according to an embodiment of the present invention. The illustrated portion of lead frame 300 includes at its center die pad 310, which is surrounded by a set of leads extending approximately radially toward a perimeter of a region which will ultimately formed the semiconductor device package (e.g., semiconductor device package 210). Leads 320 and 330 are illustrated, along with a location of the bends including and 340 and bend 350). A tie bar 410 is illustrated at the boundary regions where neighboring semiconductor device packages will be formed using the lead frame.

Lead frame 300 can be formed using a variety of processes known in the art. For example, a copper blank can be patterned and etched to form the die pad, lead, tie bar structures illustrated in FIG. 4, or a stamping process can be used to form the lead frame structures. Bends in the leads, such as bend 340 and bend 350, can be formed mechanically using, for example, a stamping process. Alternatively, bend structures can be formed during the etching process if a thicker metal blank is used.

As discussed above, embodiments of the present invention benefit from contact surfaces in the bend region (e.g. surfaces 236 and 246) having a surface plated with a metal having affinity for solder as well as being clean of any mold compound used in encapsulating of a semiconductor device package. Alternatively, the surface can be coated with, for example, an organic solderability preservative (OSP) that provides a solder wettable surface. In order to prevent mold compound from being deposited on the surface of the bend region, a mold chase having features that conform to the bend structures in the lead frame can be used during the encapsulation process of semiconductor device package 210.

FIG. 5 is a simplified block diagram illustrating a cross-section of a mold chase 510 configured to implement embodiments of the present invention. Mold chase 510 includes raised features 520, 525, 530, and 535 that are sized to conform to corresponding bend features found on a lead frame used in semiconductor device packages according to embodiments of the present invention (e.g., lead frame 300). During formation of semiconductor device package 210, mold chase 510 can be used in conjunction with a second mold chase that limits the thickness of the finished semiconductor device package. That is, the second mold chase would form a top of a region into which encapsulant can be injected and then the entire encapsulant-containing region can be subjected to heat and pressure to cure the encapsulant, thereby forming a panel or strip of encapsulated devices.

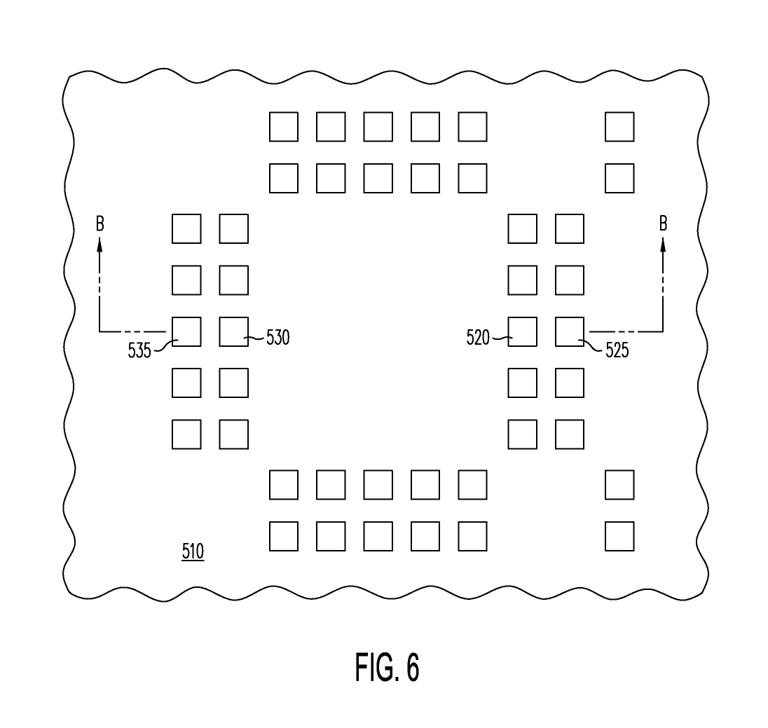

FIG. 6 is a simplified block diagram illustrating a plan view of features on mold chase 510. A set of raised features, such as step features 520, 525, 530, and 535 are arranged in a perimeter surrounding a region in which a die pad portion of a lead frame can be placed, as will be discussed more fully below. It should be noted that embodiments of the present invention are not limited to providing a lead frame with a step formed with 90° angles, such as that shown, or a mold chase having step features also having a 90° set of angles. A variety of forms can be utilized, configured such that features on the mold chase preferably conform to features in the lead frame so that mold compound does not form on portions of the lead frame intended to be exposed as contacts.

FIG. 7 is a simplified block diagram illustrating a cross-sectional view of a lead frame at a first stage of processing a semiconductor device package, incorporating embodiments of the present invention. Lead frame 710 incorporates a set of bend or step features 740, 742, 744, and 746, similar to lead frame 300. Mounted to a die pad portion of lead frame 710 is a major surface of semiconductor device die 720. Electrical contacts on an active surface of semiconductor device die 720 (not shown) are electrically coupled to contact portions of lead frame 710 by wire bonds 730. As discussed above, lead frame 710 can be formed of a conductive metal, such as copper, and have a plating metal on the bottom (as illustrated) side or both sides, where the plating metal has an affinity for bonding to solder during a reflow process (e.g., tin, gold, silver, and the like).

Semiconductor device die 720 can be any semiconductor device die appropriate to the application intended for the ultimate semiconductor device package. Embodiments of the present invention do not depend on the exact nature of semiconductor device die 720. Semiconductor device die 720 can include, for example, integrated circuits, individual devices, filters, magnetostrictive devices, electro-optical devices, electro-acoustic devices, integrated passive devices such as resistors, capacitors and inductors, or other types of elements and combinations thereof, and can be formed of any materials able to withstand an encapsulation process. Further, one or more semiconductor device die can be mounted on one or more die pads formed by the lead frame, as appropriate to the application. Semiconductor device die 720 can include a power application device die, in which the die pad portion of lead frame 710 can be configured to be a thermal conductor from a contact on the coupled major surface of semiconductor device die 720 to the die pad. Semiconductor device die 720 can be coupled to the die pad using a variety of methods, such as an adhesive (e.g., double-sided tape) or solder (e.g., for power applications), as appropriate to the application.

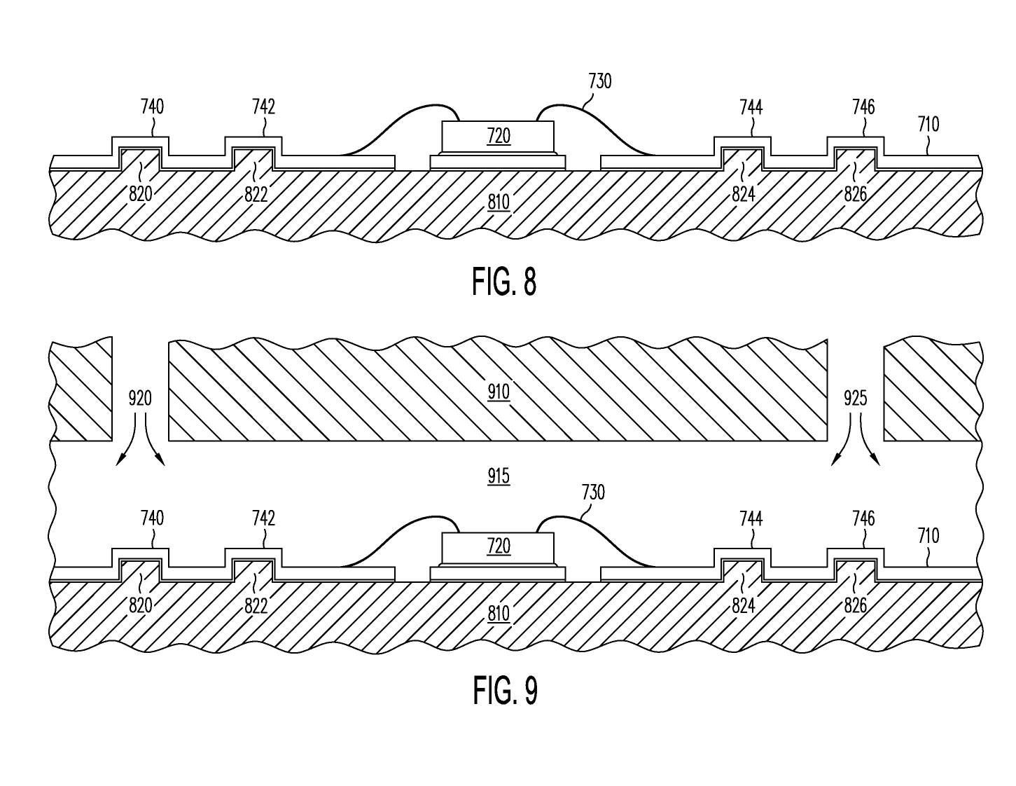

FIG. 8 is a simplified block diagram illustrating a cross-sectional view of a next stage of processing a semiconductor device package, incorporating embodiments of the present invention. Lead frame 710, including adhesively mounted semiconductor device die 720 and wire bonds 730, is placed on mold chase 810. Step features 820, 822, 824, and 826 on mold chase 810 conform to lead frame step features 740, 742, 744, and 746, respectively. Alternate embodiments can include an additional lead frame support layer, such as a polyimide, formed between the mold chase and the lead frame. This layer can be removed or otherwise modified as required by the application.

FIG. 9 is a simplified block diagram illustrating a cross-sectional view of a further stage of processing the semiconductor device package, incorporating embodiments of the present invention. A top mold chase 910 is configured above forming a region 915 into which an encapsulant can be injected, for example, through ingress ports 920 and 925. Subsequent to the injection of the encapsulant, pressure and heat can be applied to cause the encapsulant to cure, thereby forming a panel or strip of encapsulated components and the lead frame. The step features of mold chase 810 conform to the step features of lead frame 710 so that the encapsulant cannot adhere to the surfaces of the step features of the lead frame in contact with the mold chase.

The encapsulant injected into region 915 can be any appropriate encapsulant including, for example, silica-filled epoxy molding compounds, plastic encapsulation resins, and other polymeric materials such as silicones, polyimides, phenolics, and polyurethanes. As discussed above, once the molding material is applied, the panel or strip can be cured by exposing the materials to certain temperatures for a period of time, or by applying curing agents, or both, depending upon the nature of the encapsulant material and the components to be encapsulated.

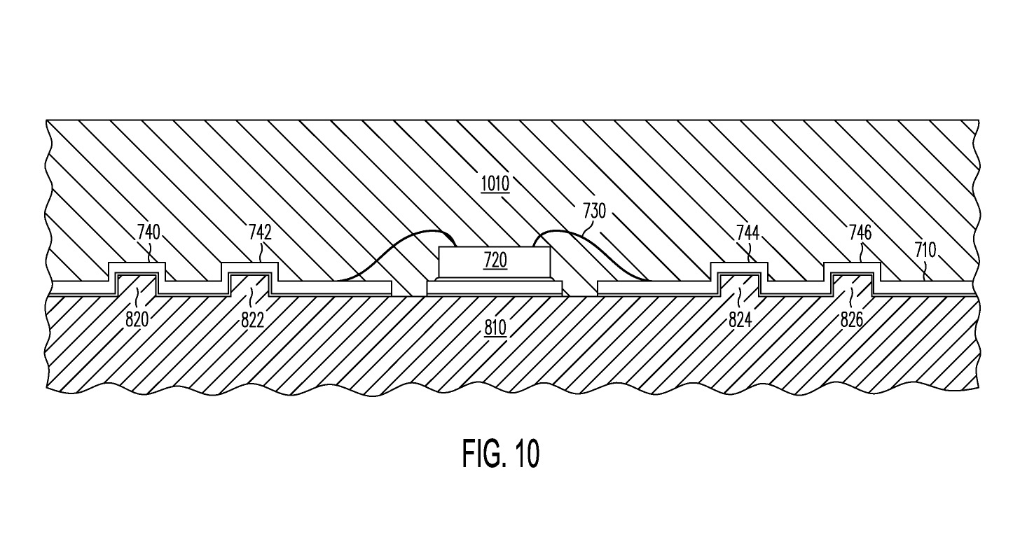

FIG. 10 is a simplified block diagram illustrating a cross-sectional view of a further stage of processing the semiconductor device package, incorporating embodiments of the present invention. Top mold chase 910 has been removed subsequent to or as a part of the curing process, exposing a top surface of the encapsulant 1010. Depending upon the application, encapsulant 1010 can be reduced in thickness by performing, for example, a grinding process, chemical etching, laser ablation, or other conventional techniques (e.g., back grinding), or alternatively by forming the encapsulant to the appropriate thickness during the encapsulation process. Alternatively, encapsulant can be added to by secondary encapsulation, depending upon the application.

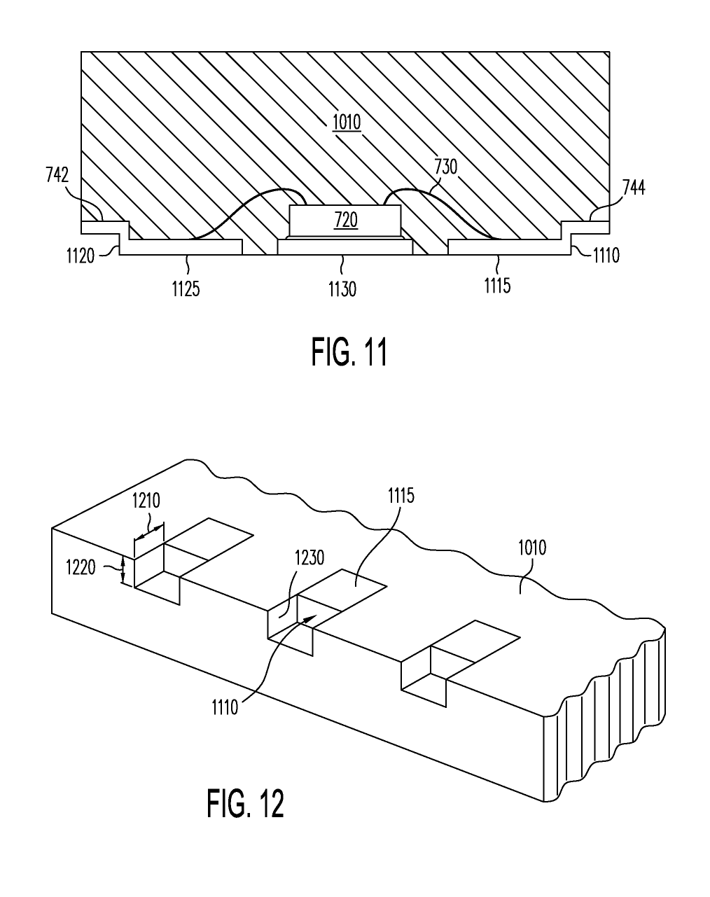

FIG. 11 is a simplified block diagram illustrating a cross-sectional view of the semiconductor device package incorporating embodiments of the present invention subsequent to singulation of the semiconductor device package from the panel or strip formed by the process illustrated in FIGS. 7-10. Singulation is performed by, for example, sawing through the panel at locations corresponding to mid-points of the lead frame step features (e.g., step features 742 and 744). Removal of the semiconductor device package from mold chase 810 and singulation exposes electrical contact step features 1110 and 1120 of electrical contacts 1115 and 1125, respectively. In addition, a die pad contact 1130 can be exposed that allows for thermal or electrical connectivity to device die 720 through a contact on the coupled major surface of device die 720 to the die pad.

As discussed above, lead frame 710 can be plated with a metal having affinity for reflowed solder prior to forming a semiconductor device assembly (e.g., by the manufacturer of the lead frame) or the exposed contacts can be plated subsequent to formation of the encapsulated semiconductor device package. Such plating can be performed either prior to singulation or subsequent to singulation, depending upon the nature of the application.

FIG. 12 is a perspective view of a portion of a bottom edge of a semiconductor device package incorporating embodiments of the present invention. Encapsulant 1010 forms the exterior portion of the semiconductor device package. Along the active surface of the semiconductor device package, which would typically be the bottom surface of the package as mounted to a PCB, is contact 1115. Contact 1115 has step feature 1110 exposed within the corner of the semiconductor device package. As discussed above, the step features have a dimension 1210 toward the center of the semiconductor device package of approximately 0.1 mm. Dimension 1210 provides a gap from the singulation region to the exposed contact (1110 and 1115) so that the contact does not change its solder wetting characteristics. Dimension 1210 can be further chosen to improve toe fillet formation from factors including optical inspection, customer requirements, and the like. The step features also have a depth 1220 toward the mid-line of the edge of the semiconductor device package that is no greater than half the overall height of the semiconductor device package. Dimension 1210 and depth 1220 correspond to dimensions of the step features of lead frame 710.

One factor in determining the dimensions of the step feature is physical characteristics of encapsulant material 1010. The exposed sidewall (e.g., 1230) of the encapsulant resulting from the formation of the contact step feature can, if too much material is exposed, be subject to cracking and other deterioration due to temperature and pressure-related effects during the solder reflow process. Further, the amount of exposed encapsulant sidewall may change results for common events such as drop survival after the semiconductor device package is bonded to a printed circuit board. Therefore, minimizing the exposed sidewall area, while still providing a sufficient surface to which the reflowed solder can attach may be desirable.

In an alternative embodiment, the step feature can be part of a continuous form along the outer perimeter of the encapsulant material. In this manner, there will be no exposed sidewall, e.g., sidewall 1230. The step feature is formed by a continuous mold chase feature in the region of the perimeter of the semiconductor device package (e.g., forming a column to replace the individual features along the column including mold chase feature 520 in FIG. 6.

Embodiments of the present invention have been shown as incorporated in an encapsulated QFN package. It should be noted that embodiments are not limited to a QFN package. Other flat no-lead packages can incorporate embodiments of the present invention, such as dual flat no-lead packages. In addition, no-lead air cavity packages can be formed that incorporate the stepped contacts of embodiments of the present invention.

By now it should be appreciated that there has been provided a semiconductor device package that includes: a body formed from an encapsulant that has first and second major surfaces, where the body includes at least one side surface coupling the first and second major surfaces and the first and second major surfaces are substantially parallel and at least a first portion of the side surface is substantially perpendicular to the first major surface and joins the first major surface at an edge of the body; and, an electrical contact with a first exposed surface on the first major surface of the semiconductor device package body and a second exposed surface substantially parallel to the first portion of the at least one side surface. The first exposed surface and the second exposed surface of the electrical contact are connected at a first bend in the electrical contact, the first exposed surface and the second exposed surface of electrical contact include a solderable surface, and the second exposed surface of the electrical contact is recessed from the first portion of the at least one side surface.

In one aspect of the above embodiment, the electrical contact includes a first metal layer comprising copper, and a second metal layer over the first metal layer that includes a solderable surface. The solderable surface provides the first exposed surface and the second exposed surface of the electrical contact. In a further aspect, the second metal layer includes one or more of tin, gold, silver, nickel, and palladium. In another further aspect, the semiconductor device package further includes a portion of a lead frame encapsulated in the body of the semiconductor device package, where the portion of the lead frame includes the electrical contact and a die pad, and a semiconductor device die, adhesively coupled to the die pad and electrically coupled to the electrical contact.

In still another further aspect, the electrical contact further includes a third exposed surface substantially parallel to the first major surface extending to an end flush with the first portion of the side surface, where the third exposed surface and the second exposed surface are connected at a second bend in the electrical contact. In a further aspect, a length of the electrical contact from the first bend to the second bend is less than or equal to half a distance between the first and second major surfaces. In another further aspect, a length of the electrical contact from the second bend to the end of the electrical contact is 0.1 mm.

Another embodiment provides a method for forming a semiconductor device package. The method includes: providing a conductive metal lead frame, where the lead frame includes a die pad configured to mount a semiconductor device die and a plurality of leads. Each lead of the plurality of leads includes: a first end and a second end wherein the first end is closer to the die pad than the second end; a first length of the lead extending from the first end to a first bend wherein the first bend forms a first angle up from a plane formed by the die pad and the first length of the lead; a second length of the lead extending from the first bend to a second bend wherein the second bend forms a second angle toward the plane formed by the die pad and the first length of the lead; a third length of the lead extending from the second bend to a third bend wherein the third bend forms a third angle; a fourth length of the lead extending from the third bend to the plane formed by the die pad and the first length of the lead; and, a fifth length of the lead extending from a fourth bend along the plane formed by the die pad and the first length of the lead wherein the fifth length of the lead and the fourth length of the lead are coupled at the fourth bend.

One aspect of the above embodiment further includes coating a bottom surface of each of the plurality of leads with a solderable surface, where a top surface of each lead is a surface in the direction of the first bend and the bottom surface is a surface opposite the top surface. In a further aspect, said coating includes a plating process and the solderable surface includes one or more of tin, gold, silver, palladium, and nickel, and the conductive metal of the lead frame comprises copper. In another further aspect, the method further includes mounting one or more semiconductor device die on the die pad and electrically coupling a contact of one of the one or more semiconductor device die to a lead of the plurality of leads. In yet a further aspect, electrically coupling includes forming a wire bond from the contact of the one of the one or more semiconductor device die to the lead of the plurality of leads.

In another further aspect, the method further includes placing the lead frame on a mold chase. The bottom surface of the lead frame is in contact with the surface of the mold chase, and the mold chase includes one or more features configured to conform to the bottom surface of the region of each lead that includes the second, third, and fourth lengths and the first, second, third, and fourth bends. Further to this aspect, the method includes forming an encapsulant over and around sides of the one or more semiconductor device die and over and around the lead frame, wherein the mold chase prevents encapsulant from forming along the bottom surface of the plurality of leads. Again further to this aspect, the method includes singulating the semiconductor device package from a neighboring semiconductor device by cutting through the encapsulant in a location along the third length of a set of leads of the plurality of leads along a corresponding edge of the semiconductor device package.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

1. A semiconductor device package comprising:
a body formed from an encapsulant, wherein
the body comprises first and second major surfaces,
the body comprises at least one side surface coupling the first and second major surfaces, and
the first and second major surfaces are substantially parallel and at least a first portion of the side surface is substantially perpendicular to the first major surface and joins the first major surface at an edge of the body;
an electrical contact having a first exposed surface on the first major surface of the semiconductor device package body and a second exposed surface substantially parallel to the first portion of the at least one side surface, wherein
the first exposed surface and the second exposed surface of the electrical contact are connected at a first bend in the electrical contact,
the first exposed surface and the second exposed surface of the electrical contact are comprised of a solderable metal, and
the second exposed surface of the electrical contact is recessed from the first portion of the at least one side surface.

2. The semiconductor device package of claim 1 wherein the electrical contact comprises:
a first metal layer comprising copper; and
a second metal layer coating the first metal layer and comprising a solderable surface, wherein the first exposed surface and the second exposed surface of the electrical contact comprise the solderable surface.

3. The semiconductor device package of claim 2 wherein the second metal layer comprises one or more of tin, lead, gold, silver, nickel, and palladium.

4. The semiconductor device package of claim 2 further comprising:
a portion of a lead frame encapsulated in the body of the semiconductor device package, wherein the portion of the lead frame comprises the electrical contact and a die pad;
a semiconductor device die, adhesively coupled to the die pad, and electrically coupled to the electrical contact.

5. The semiconductor device package of claim 2 wherein the electrical contact further comprises:
a third exposed surface substantially parallel to the first major surface extending to an end flush with the first portion of the side surface, wherein the third exposed surface and the second exposed surface are connected at a second bend in the electrical contact.

6. The semiconductor device package of claim 5, wherein a length of the electrical contact from the first bend to the second bend is less than or equal to two-thirds of a distance between the first and second major surfaces.

7. The semiconductor device package of claim 5, wherein a length of the electrical contact from the second bend to the end of the electrical contact is 0.1 mm.

8. A method for forming a semiconductor device package, the method comprising:
providing a conductive metal lead frame, wherein the lead frame comprises
a die pad configured to mount a semiconductor device die,
a plurality of leads wherein each lead of the plurality of leads comprises
a first end and a second end wherein the first end is closer to the die pad than the second end,
a first length of the lead extending from the first end to a first bend wherein the first bend forms a first angle up from a plane formed by the die pad and the first length of the lead,
a second length of the lead extending from the first bend to a second bend wherein the second bend forms a second angle toward the plane formed by the die pad and the first length of the lead,
a third length of the lead extending from the second bend to a third bend wherein the third bend forms a third angle,
a fourth length of the lead extending from the third bend to the plane formed by the die pad and the first length of the lead, and
a fifth length of the lead extending from a fourth bend along the plane formed by the die pad and the first length of the lead wherein the fifth length of the lead and the fourth length of the lead are coupled at the fourth bend.

9. The method of claim 8 further comprising:
coating a bottom surface of each of the plurality of leads with a solderable surface, wherein a top surface of each lead is a surface in the direction of the first bend and the bottom surface is a surface opposite the top surface.

10. The method of claim 9 wherein said coating comprises plating, and the solderable surface comprises one or more of tin, gold, silver, palladium and nickel and the conductive metal of the lead frame comprises copper.

11. The method of claim 9 further comprising:
mounting one or more semiconductor device die on the die pad; and
electrically coupling a contact of one of the one or more semiconductor device die to a lead of the plurality of leads.

12. The method of claim 11 wherein said electrically coupling comprises forming a wire bond from the contact of the one of the one or more semiconductor device die to the lead of the plurality of leads.

13. The method of claim 11 further comprising:
placing the lead frame on a mold chase, wherein
the bottom surface of the lead frame is in contact with the surface of the mold chase, and
the mold chase comprises one or more features configured to conform to the bottom surface of the region of each lead that comprises the second, third, and fourth lengths and the first, second, third, and fourth bends.

14. The method of claim 13 further comprising:
forming an encapsulant over and around sides of the one or more semiconductor device die and over and around the lead frame, wherein
the mold chase prevents encapsulant from forming along at least the bottom surface of the plurality of leads.

15. The method of claim 14 further comprising:
singulating the semiconductor device package from a neighboring semiconductor device by cutting through the encapsulant in a location along the third length of a set of leads of the plurality of leads along a corresponding edge of the semiconductor device package.
